(19) United States
(12) Patent Application Publication
(10) Pub. No.: US 2017/0307981 A1
(43) Pub. Date: Oct. 26, 2017

(54) EXPOSURE METHOD AND EXPOSURE MACHINE

(71) Applicant: SHENZHEN CHINA STAR OPTOELECTRONICS TECHNOLOGY CO., LTD., Shenzhen, Guangdong (CN)

(72) Inventor: Jiangjiang SONG, Shenzhen, Guangdong (CN)

(21) Appl. No.: 14/416,317

(22) PCT Filed: Sep. 4, 2014
(86) PCT No.: PCT/CN2014/085902

§ 371 Date: May 9, 2016

(30) Foreign Application Priority Data
Aug. 14, 2014 (CN) 201410400540.9

(51) Int. Cl. G03F 7/20

(52) U.S. Cl. CPC G03F 7/2045

(57) ABSTRACT

An exposure method and an exposure machine according to the present disclosure, which can achieve higher exposure accuracy, belong to the technical field of display. The exposure method comprises the following steps: a mask is placed at a first position above a substrate to be exposed; a first region of a photoresist on the substrate is exposed; the mask is moved to a second position above the substrate; and a second region of the photoresist on the substrate is exposed. As a result, an overlapped region between the first region and the second region of the photoresist is exposed twice. The present disclosure is applicable to the manufacturing of a liquid crystal display device.

The present application claims benefit of Chinese patent application CN 201410400540.9, entitled “Exposure Method and Exposure Machine” and filed on Aug. 14, 2014, which is incorporated herein by reference.

### TECHNICAL FIELD

The present disclosure relates to the technical field of display, and in particular to an exposure method and an exposure machine.

### TECHNICAL BACKGROUND

As display technology develops, liquid crystal display has become the most commonly used display device.

During the manufacturing of a liquid crystal display, a patterning process will be performed repeatedly. Specifically, a mask is placed above a substrate coated with photoresist, and then the substrate is exposed with an exposure machine. Based on the pattern formed on the mask, there would be an exposed part and an unexposed part on the photoresist. Subsequently, by developing the photoresist with developing solution, the exposed part of the photoresist is removed and the unexposed part is retained (if positive photoresist is used), or the unexposed part is removed and the exposed part is retained (if negative photoresist is used), thereby desired patterns can be formed on the photoresist.

However, the exposure accuracy of the existing exposure machine is generally low, i.e., the dimensional accuracy that can be achieved by the exposure machine is not small enough. As a result, the size of the pattern formed by the photoresist is relatively large. In addition, there is inevitably foreign matters on the exposed substrate, which exceeds the surface of the substrate and the photoresist. In this case, the distance between the mask and the photoresist cannot be sufficiently small, which is one of the main reasons causing insufficient exposure accuracy. Therefore, the current demand for high precision structure of the liquid crystal display can hardly be satisfied due to the problem of low exposure accuracy in the prior art.

### SUMMARY OF THE INVENTION

The objective of the present disclosure is to provide an exposure method and an exposure machine for achieving higher exposure accuracy.

The present disclosure provides an exposure method, comprising:

placing a mask at a first position above a substrate to be exposed,

exposing a first region of a photoresist on the substrate,

moving the mask to a second position above the substrate, and

exposing a second region of the photoresist on the substrate, so that an overlapped region between the first region and the second region is exposed twice.

Preferably, the displacement between the second position and the first position is smaller than the dimensional accuracy of an exposure machine used in the exposure method.

Preferably, the photoresist is negative photoresist,

and the method further comprises:

retaining the region that is exposed twice,

and removing regions that are exposed once and regions that are not exposed.

Preferably, the substrate is a color filter substrate, and the photoresist is used for forming a color filter layer.

Preferably, each of the two exposures is performed with an exposure quantity below 25 mJ.

The present disclosure further provides an exposure machine, comprising:

a light source,

a base for placing the substrate to be exposed,

a carrying table for placing the mask, and

a driver for driving the carrying table, so that the carrying table can move in parallel with the base.

Preferably, the driver is a motor or a hydraulic machine.

Preferably, the dimensional accuracy of the exposure machine is 8 μm.

The present disclosure has the following beneficial effects. In the exposure method according to the present disclosure, a first region and a second region of the photoresist are respectively exposed, each exposure using relatively small exposure quantity. The overlapped area between the first region and the second region is exposed twice, such that a saturated exposure in the overlapped area can be achieved, and the regions exposed only once are underexposed. After development, only the region of the pattern formed by the photoresist that is exposed twice is removed (positive photoresist) or retained (negative photoresist).

Because the region exposed twice is the overlapped region between the first region and the second region, and the size thereof is determined by the displacement of the mask between the first position and the second position, the region that is exposed twice can be configured as having any size through adjusting the first position and the second position of the mask, without being limited by the exposure accuracy of the exposure machine itself. Therefore, in the technical solution according to the present disclosure, higher exposure accuracy can be realized under the condition of relatively low exposure accuracy of the exposure machine, thereby the demand for high precision structure of a liquid crystal display can be satisfied.

Other features and advantages of the present disclosure will be further explained in the following description and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE ACCOMPANYING DRAWINGS

In order to illustrate the technical solutions of the embodiments of the present disclosure, the drawings relating to the embodiments will be explained briefly. In which:

FIG. 1 schematically shows a step of an exposure method according to example 1 of the present disclosure,

FIG. 2 schematically shows a further step of the exposure method according to example 1 of the present disclosure,

FIG. 3 schematically shows an exposure machine according to example 1 of the present disclosure, and

FIG. 4 schematically shows an exposure method according to example 2 of the present disclosure.

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. It is important to note that as long as there is no structural conflict, all the technical features mentioned in all the embodiments may be combined together in any manner, and the technical solutions obtained in this manner all fall within the scope of the present disclosure.

### EXAMPLE 1

According to an example of the present disclosure, an exposure method is provided. In this example, a color filter layer is formed on a color filter substrate through the exposure method.

The exposure method comprises the following steps.

In step 1, a mask is placed at a first position above a substrate to be exposed. In this step, the substrate is coated with photoresist (which will finally form the color filter layer). The photoresist used in the present example is negative photoresist commonly used in the manufacturing of color filter layer.

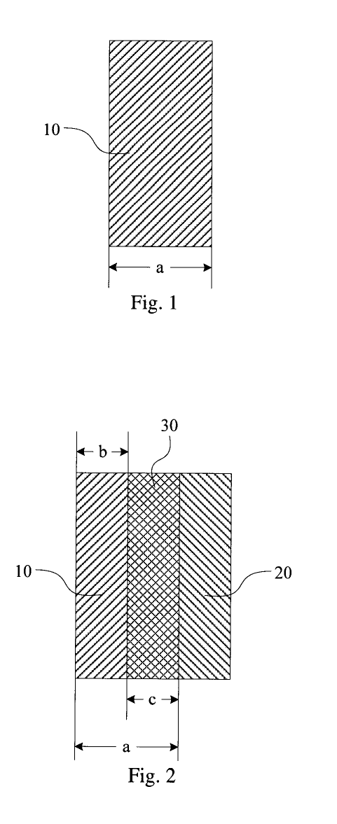

In step 2, a first region 10 of the photoresist on the substrate is exposed, as shown in FIG. 1. In this example, the dimensional accuracy of the exposure machine is 8 μm, i.e., the smallest size a of the exposed first region is 8 μm. In addition, the regular exposure quantity of negative photoresist is generally 50 mJ. The exposure quantity used in step 2 should be smaller than the regular exposure quantity, which can be selected as below 25 mJ.

In step 3, the mask is moved to a second position above the substrate. In a preferred solution, the displacement between the second position and the first position is smaller than the dimensional accuracy of an exposure machine used in the exposure method.

In step 4, a second region 20 of the photoresist on the substrate is exposed, as shown in FIG. 2, and thus an overlapped region 30 between the first region 10 and the second region 20 is exposed twice.

Because in step 3 the mask is moved from the left to the right with a distance b, which is 4 μm, a width c of the overlapped region 30 between the first region 10 and the second region 20 is 4 μm.

Preferably, the exposure quantity in this step equals to that in step 2.

In step 5, the photoresist is developed with developing solution. The region 30 of the photoresist that is exposed twice is retained, and the regions thereof that are exposed once or unexposed are removed.

Because the overlapped region 30 between the first region 10 and the second region 20 is exposed twice, a saturated exposure of the overlapped region 30 can be achieved. In this case, the photochromics in the photoresist can experience a sufficient cross-linking reaction. Therefore, after development, the region 30 that is exposed twice is retained.

In the first region 10 and the second region 20, the parts that are exposed once suffer from underexposure, and thus the photochromics therein do not experience a sufficient cross-linking reaction. The regions of the photoresist outside the first region 10 and the second region 20 are not exposed at all, and thus no cross-linking reaction occurs to the photochromics therein. Therefore, after development, the regions that are exposed once and those that are not exposed are removed.

Because the region that is exposed twice is the overlapped region 30 between the first region 10 and the second region 20, and the size thereof is determined by the displacement of the mask between the first position and the second position, the region 30 that is exposed twice can be configured as having any size by adjusting the first position and the second position of the mask, without being limited by the exposure accuracy of the exposure machine itself. In the present example, the smallest width of the pattern formed by the photoresist is 4 μm, which is smaller than the inherent dimensional accuracy of 8 μm of the exposure machine. Therefore, with the exposure method according to the present disclosure, higher exposure accuracy can be realized under the condition of relatively low exposure accuracy of the exposure machine, thereby the demand for high precision structure of the liquid crystal display can be satisfied.

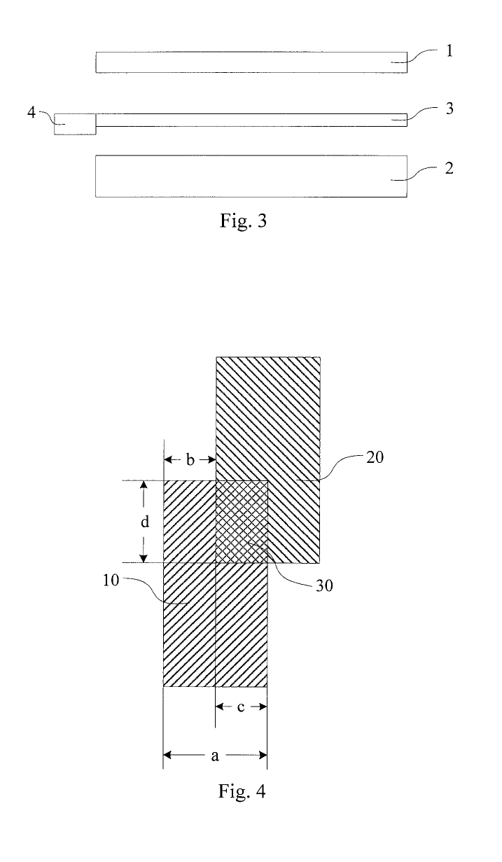

As shown in FIG. 3, the present disclosure further provides an exposure machine, comprising a light source 1, a base 2, a carrying table 3, and a driver 4. The base 2 is used for placing the substrate to be exposed, and the carrying table 3 is used for placing the mask. The driver 4 is preferably a motor or a hydraulic machine for driving the carrying table 3, so that the carrying table 3 can move in parallel with the base 2.

The above exposure method can be implemented through the exposure machine according to an example of the present disclosure.

Specifically, in step 1, a substrate coated with photoresist is placed on the base 2, and a mask is placed on the carrying table 3, so that the mask is located at a first position above the substrate.

In step 2, the light source is turned on for exposing a first region of the photoresist of the substrate.

In step 3, after the first region is exposed, the carrying table 3 is driven by the driver 4, so that the mask is moved to a second position above the substrate.

Subsequently, in step 4, the light source 1 is turned on again and the second region of the photoresist is exposed, so that the overlapped region between the first region and the second region of the photoresist is exposed twice.

Finally, in step 5, the photoresist is developed with developing solution.

In this case, the size of the pattern formed by the photoresist is smaller than the inherent dimensional accuracy of the exposure machine, so that under the condition that the exposure accuracy of the exposure machine is relatively low, higher exposure accuracy can be realized, thereby the demand for high precision structure of the liquid crystal display can be satisfied.

It should be noted that in other embodiments, an array substrate or other components can also be manufactured by the exposure method and the exposure machine according to the present disclosure. Certainly, the photoresist used can also be positive photoresist.

### EXAMPLE 2

The exposure method according to example 2 is substantially the same with that in example 1. The difference of the exposure method in this example is that in step 3, the mask is moved along an oblique direction.

As shown in FIG. 4, after the oblique movement of the mask, between a first region 10 and a second region 20, there is not only a horizontal displacement b, but also a lateral displacement d. After a second exposure and a development process, higher exposure accuracy can be achieved for the pattern formed by the photoresist in both a lateral dimension and a horizontal dimension, thereby demand for high precision structure of the liquid crystal display can be realized in both a lateral direction and a longitudinal direction.

The above embodiments are described only for better understanding, rather than restricting, the present disclosure. Any person skilled in the art can make amendments to the implementing forms or details without departing from the spirit and scope of the present disclosure. The scope of the present disclosure should still be subjected to the scope defined in the claims.

1. An exposure method, comprising:
placing a mask at a first position above a substrate to be exposed,
exposing a first region of a photoresist on the substrate,
moving the mask to a second position above the substrate, and
exposing a second region of the photoresist on the substrate, so that an overlapped region between the first region and the second region is exposed twice.

2. The method according to claim 1, wherein the displacement between the second position and the first position is smaller than the dimensional accuracy of an exposure machine used in the exposure method.

3. The method according to claim 1, wherein the photoresist is negative photoresist, and the method further comprises:
retaining the region that is exposed twice,
and removing regions that are exposed once and regions that are not exposed.

4. The method according to claim 3, wherein the substrate is a color filter substrate, and the photoresist is used for forming a color filter layer.

5. The method according to claim 1, wherein each of the two exposures is performed with an exposure quantity below 25 mJ.

6. An exposure machine, comprising:
a light source,
a base for placing the substrate to be exposed,
a carrying table for placing the mask, and
a driver for driving the carrying table, so that the carrying table can move in parallel with the base.

7. The exposure machine according to claim 6, wherein the driver is a motor or a hydraulic machine.

8. The exposure machine according to claim 6, wherein the dimensional accuracy of the exposure machine is 8 μm.
